(19) United States
(12) Patent Application Publication
(10) Pub. No.: US 2024/0352619 A1
(43) Pub. Date: Oct. 24, 2024

(54) CRYSTAL LAMINATION STRUCTURE, SEMICONDUCTOR DEVICE, AND METHOD OF MANUFACTURING CRYSTAL LAMINATION STRUCTURE

(71) Applicants: Mitsubishi Electric Corporation, Tokyo (JP); NATIONAL UNIVERSITY CORPORATION TOKYO UNIVERSITY OF AGRICULTURE AND TECHNOLOGY, Tokyo (JP)

(72) Inventors: Yohei YUDA, Tokyo (JP); Tatsuro WATAHIKI, Tokyo (JP); Yoshinao KUMAGAI, Tokyo (JP); Ken GOTO, Tokyo (JP)

(73) Assignee: Mitsubishi Electric Corporation, Tokyo (JP)

(21) Appl. No.: 18/685,510

(22) PCT Filed: Sep. 3, 2021
(86) PCT No.: PCT/JP2021/032392

§ 371 Date: Feb. 22, 2024

(51) Int. Cl. C30B 25/10; H01L 29/04; H01L 29/24; H01L 29/812

(52) U.S. Cl. CPC C30B 25/10; H01L 29/045; H01L 29/24; H01L 29/812

(57) ABSTRACT

An object is to provide a technique capable of increasing device characteristics. A crystal lamination structure includes a Ga₂O₃ single-crystal substrate having a first main surface. The crystal lamination structure includes a Ga₂O₃ single-crystal layer as an epitaxial growth layer provided on the first main surface of the Ga₂O₃ single-crystal substrate and having a second main surface on a side opposite to the Ga₂O₃ single-crystal substrate. A plane direction of the first main surface of the Ga₂O₃ single-crystal substrate is plane. A plane direction of the second main surface of the Ga₂O₃ single-crystal layer is plane.

### TECHNICAL FIELD

The present disclosure relates to a crystal lamination structure, a semiconductor device, and a method of manufacturing the crystal lamination structure.

### BACKGROUND ART

Recently, a material used for a semiconductor element is shifting to a widegap semiconductor (also referred to as a wide bandgap semiconductor) to achieve high withstand voltage of the semiconductor element. A Schottky barrier diode using gallium oxide as a type of the widegap semiconductor can increase reverse withstand voltage compared with a Schottky barrier diode using silicon (Si) and silicon carbide (SiC), for example. Various techniques are proposed for such a Schottky barrier diode using gallium oxide (for example, Patent Documents 1 and 2).

### PRIOR ART DOCUMENTS

### Patent Document(S)

Patent Document 1: Japanese Patent Application Laid-Open No. 2020-096197

Patent Document 2: Japanese Patent Application Laid-Open No. 2016-029735

### SUMMARY

### Problem to be Solved by the Invention

However, there is a problem that in the semiconductor element using gallium oxide, increase in a defect density of an epitaxial growth layer of gallium oxide causes reduction in device characteristics.

The present disclosure is therefore has been made to solve problems as described above, and it is an object to provide a technique capable of increasing device characteristics.

### Means to Solve the Problem

A crystal lamination structure according to the present disclosure includes: a Ga₂O₃ single-crystal substrate having a first main surface; and a Ga₂O₃ single-crystal layer as an epitaxial growth layer provided on the first main surface of the Ga₂O₃ single-crystal substrate and having a second main surface on a side opposite to the Ga₂O₃ single-crystal substrate, wherein a plane direction of each of the first main surface of the Ga₂O₃ single-crystal substrate and the second main surface of the Ga₂O₃ single-crystal layer is (011) plane.

### Effects of the Invention

According to the present disclosure, the plane direction of each of the first main surface of the Ga₂O₃ single-crystal substrate and the second main surface of Ga₂O₃ single-crystal layer is the (011) plane. According to such a configuration, device characteristics can be increased.

These and other objects, features, aspects and advantages of the present disclosure will become more apparent from the following detailed description and the accompanying drawings.

### BRIEF DESCRIPTION OF DRAWINGS

FIG. 1 A cross-sectional view schematically exemplifying a Ga₂O₃ single-crystal lamination structure according to an embodiment 1.

FIG. 2 A perspective view illustrating a plane direction according to the embodiment 1.

FIG. 3 A schematic view for explaining the plane direction according to the embodiment 1.

FIG. 4 A cross-sectional view schematically exemplifying a vapor-phase growth device according to the embodiment 1.

FIG. 5 A cross-sectional view schematically exemplifying a semiconductor device according to an embodiment 2.

FIG. 6 A cross-sectional view schematically exemplifying a semiconductor device according to an embodiment 3.

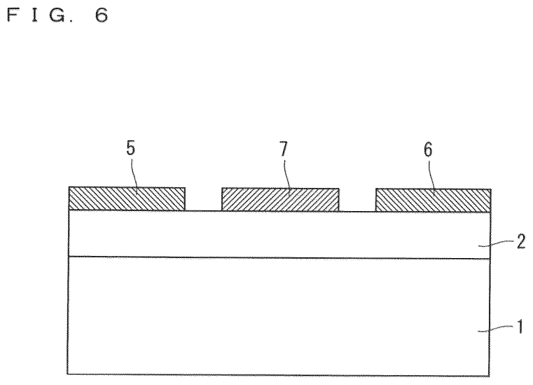

### DESCRIPTION OF EMBODIMENT(S)

The present embodiment is described hereinafter with reference to the accompanying drawings. The drawings are schematically shown, and a configuration is appropriately omitted or simplified in the drawings hereinafter. A mutual relationship of sizes and positions of configurations illustrated in the different drawing is not necessarily accurately illustrated, but can be appropriately changed.

In the description hereinafter, the same reference numerals are assigned to the similar constituent elements in the illustration, and the same applies to names and functions thereof. Accordingly, the detailed description on similar constituent elements, for example, may be omitted to avoid a repetition in some cases.

### Embodiment 1

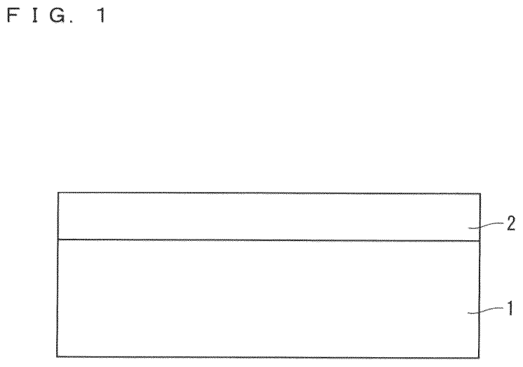

FIG. 1 is a cross-sectional view schematically exemplifying a Ga₂O₃ single-crystal lamination structure as a crystal lamination structure according to the present embodiment 1. The Ga₂O₃ single-crystal lamination structure includes a Ga₂O₃ single-crystal substrate 1 and a Ga₂O₃ epitaxial growth layer 2 formed on a main surface of the Ga₂O₃ single-crystal substrate 1. A method of forming the Ga₂O₃ epitaxial growth layer 2 is not particularly limited as long as it is a method of forming a Ga₂O₃ single-crystal layer (also referred to as a Ga₂O₃ single-crystal film) using epitaxial growth.

The Ga₂O₃ single-crystal substrate 1 is a substrate made up of a Ga₂O₃ series single crystal having a β-type crystal structure. In the description hereinafter, β-Ga₂O₃ is a base of a material of the Ga₂O₃ single-crystal substrate 1. However, the material of the Ga₂O₃ single-crystal substrate 1 is not limited thereto, but may also be an oxidized material containing Ga as a main component to which at least one group made of copper (Cu), silver (Ag), zinc (Zn), cadmium (Cd), aluminum (Al), indium (In), silicon (Si), germanium (Ge), tin (Sn), iron (Fe), or magnesium (Mg) is added.

As an example thereof, a gallium oxide expressed by (AlₓIn_{y}Ga_{1-x-y})₂O₃ (wherein, 0≤x<1, 0≤y<1, 0≤x+y<1 are satisfied) can be used as the material of the Ga₂O₃ single-crystal substrate 1. When Al is added, a bandgap of the Ga₂O₃ single-crystal substrate 1 is widened, and when In is added, a bandgap of the Ga₂O₃ single-crystal substrate 1 is narrowed. The material of the Ga₂O₃ single-crystal substrate 1 may include a conductive impurity such as Si. The Ga₂O₃ single-crystal substrate 1 may be any of a substrate indicating n-type conductivity with only oxygen defect, a substrate indicating n-type conductivity with an n-type impurity, and a substrate indicating n-type conductivity with both oxygen defect and an n-type impurity.

The Ga₂O₃ single-crystal substrate 1 is formed by slicing bulk crystal of Ga₂O₃ series single crystal generated by a melt growth method such as floating zone (FZ) method or an edge-defined film-fed growth (EFG) method, for example, and polishing a surface thereof. An electronic carrier concentration of the Ga₂O₃ single-crystal substrate 1 is determined by an amount of oxygen defect formed in manufacturing the Ga₂O₃ single-crystal substrate 1 and an amount of an impurity of Si and Sn, for example. The electronic carrier concentration in the Ga₂O₃ single-crystal substrate 1 can be controlled by controlling an amount of impurity and an activation rate thereof.

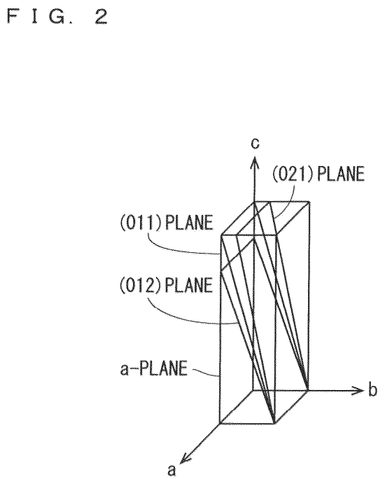

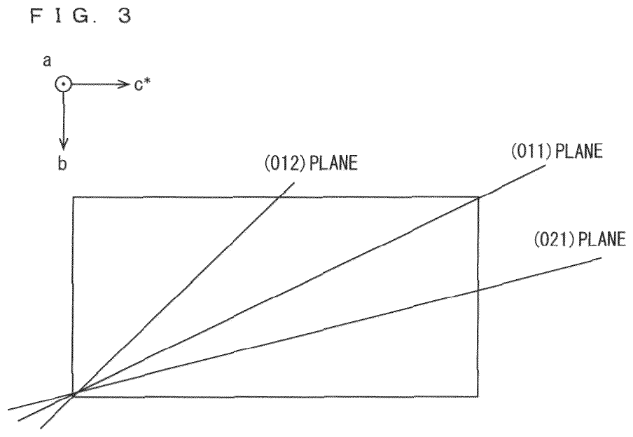

The Ga₂O₃ single-crystal substrate 1 includes a first main surface, and the first main surface is an upper surface in the example in FIG. 1. A plane direction of the first main surface is preferably (011) plane, and an offset angle with respect to the (011) plane of the first main surface is most preferably 0°. However, it is sufficient that the plan direction of the first main surface is a plane direction between (021) plane and (012) plane except for (021) plane and (012) plane. This configuration is described hereinafter using FIG. 2 and FIG. 3.

FIG. 2 is a perspective view illustrating a plane direction of β-Ga₂O₃. Crystal of β-Ga₂O₃ is a monoclinic crystal system, thus (100) plane is a plane parallel to a plane made by a b-axis and a c-axis (that is to say, a bc plane).

FIG. 3 is a schematic view illustrating an offset angle in a case of seeing an a-plane in front of an origin point of three lattice vectors, that is to say, the (100) plane along a lattice vector of an a-axis. An asterisk assigned to the c-axis indicates that the c-axis inclined in a back side direction of FIG. 3 is expressed as a direction in a conventional drawing.

When a rotation direction of a right screw proceeding from the origin to the a-plane along the a-axis direction (corresponding to counterclockwise rotation direction in FIG. 3) is a positive direction, it is sufficient that the plane direction of the first main surface is a plane direction of being rotated with 18.8292° or less in the positive direction from the (011) plane. In other words, it is sufficient that the offset angle with respect to the (011) plane of the first main surface is an angle to such an extent that the (012) plane does not appear as the plane direction of the first main surface. It is sufficient that the plane direction of the first main surface is a plane direction of being rotated with 13.2504° or less in a negative direction from the (011) plane. In other words, it is sufficient that the offset angle with respect to the (011) plane of the first main surface is an angle to such an extent that the (021) plane does not appear as the plane direction of the first main surface.

The Ga₂O₃ epitaxial growth layer 2 is made up of a Ga₂O₃ series single crystal having a β-type crystal structure in the manner similar to the Ga₂O₃ single-crystal substrate 1. The Ga₂O₃ epitaxial growth layer 2 may include a conductive impurity such as Si in the manner similar to the Ga₂O₃ single-crystal substrate 1. The Ga₂O₃ epitaxial growth layer 2 may be any of a layer indicating n-type conductivity with only oxygen defect, a layer indicating n-type conductivity with an n-type impurity, and a layer indicating n-type conductivity with both oxygen defect and an n-type impurity in the manner similar to the Ga₂O₃ single-crystal substrate 1. The electronic carrier concentration of the Ga₂O₃ epitaxial growth layer 2 can be adjusted by controlling a supply amount of impurity or oxygen defect in an epitaxial growth, for example.

The Ga₂O₃ epitaxial growth layer 2 is provided on the first main surface of the Ga₂O₃ single-crystal substrate 1, and has a second main surface on a side opposite to the Ga₂O₃ single-crystal substrate 1. In the example in FIG. 1, the second main surface is an upper surface.

A plane direction of the second main surface of the Ga₂O₃ epitaxial growth layer 2 is preferably (011) plane, and an offset angle with respect to the (011) plane of the second main surface is most preferably 0°. However, it is sufficient that the plan direction of the second main surface is a plane direction between (021) plane and (012) plane except for (021) plane and (012) plane. That is to say, it is sufficient that the plane direction of the second main surface is a plane direction of being rotated with 18.8292° or less in the positive direction from the (011) plane, and the offset angle with respect to the (011) plane of the second main surface is an angle to such an extent that the (012) plane does not appear as the plane direction of the second main surface. It is sufficient that the plane direction of the second main surface is a plane direction of being rotated with 13.2504º or less in the negative direction from the (011) plane, and in other words, the offset angle with respect to the (011) plane of the second main surface is an angle to such an extent that the (021) plane does not appear as the plane direction of the second main surface.

Generally known is that defect is formed in a single-crystal substrate by various factors in forming the Ga₂O₃ single-crystal substrate. For example, in the Ga₂O₃ single-crystal substrate having the (001) plane as a main surface, defect caused by a slide plane appears on the main surface. When an epitaxial growth layer is formed on the single-crystal substrate, the defect is carried over to the epitaxial growth layer, and also appears on the main surface of the epitaxial growth layer.

In contrast, in a configuration that the plane direction of each of the first main surface and the second main surface is the (011) plane and a plane in proximity to the (011) plane as with the present embodiment 1, suppressed is appearance of the defect caused by the slide plane on the first main surface and the second main surface, thus a defect density can be reduced. The defect density as a factor having direct influence on characteristics of a device is reduced, thus leakage current of the device can be reduced, or reverse withstand voltage can be increased, and the device characteristics can be increased.

### Manufacturing Method

An epitaxial growth of the Ga₂O₃ epitaxial growth layer 2 is mainly described in a method of manufacturing the Ga₂O₃ single-crystal lamination structure according to the present embodiment 1. Described hereinafter is a case of using a halide vapor phase epitaxy (HVPE) method in forming the Ga₂O₃ epitaxial growth layer 2, however, the method is not limited thereto. For example, a molecular beam epitaxy (MBE) method, a pulsed laser deposition (PLD) method, a metal organic chemical vapor deposition (MOCVD) method, or a mist CVD may be used for the method of forming the Ga₂O₃ epitaxial growth layer 2.

An epitaxial growth can be performed on the Ga₂O₃ single-crystal substrate 1 by supplying gallium vapor and oxygen series gas in a vacuum chamber in the MBE method, however, a growth rate is relatively low, and it takes a long time to form a thick layer, thus the MBE method is unsuitable for mass production. In the PLD method, a source as a material supply source from which a material is supplied to the substrate is a point source, and a growth rate is different between a position immediately above the source and the other position, and an in-plane distribution of a film thickness is easily uneven, thus the PLD method is unsuitable for growth of a film having a large area. In the PLD method, a growth rate is relatively low, thus the PLD method is unsuitable for mass production. In the mist CVD method, a large diameter can be achieved relatively easily, however, impurity included in a raw material which is used is taken in the Ga₂O₃ single-crystal layer in the epitaxial growth, thus it is difficult to obtain a Ga₂O₃ epitaxial growth layer having high impurity.

In contrast, in the HVPE method, a deposition rate of a Ga₂O₃ epitaxial growth layer is high compared with the MBE method and the PLD method, for example, uniformity of an in-plane distribution of a film thickness is high, and a large diameter can be achieved, thus the HVPE method is suitable for mass production.

FIG. 3 is a cross-sectional view schematically exemplifying a vapor-phase growth device for the HVPE method. The vapor-phase growth device for the HVPE method includes a reaction chamber 20 and a first heating means 26 and a second heating means 27 disposed around the reaction chamber 20 to heat an inner side of the reaction chamber 20.

The reaction chamber 20 includes a raw material reaction region R1 and a crystal growth region R2. A reaction container 25 housing a gallium raw material is disposed in a raw material reaction region R1, and gallium chloride series gas is generated. In the present embodiment 1, the gallium raw material housed in the reaction container 25 is a gallium metal body, but is not limited thereto.

The Ga₂O₃ single-crystal substrate 1 is disposed in the crystal growth region R2, and growth of the Ga₂O₃ epitaxial growth layer 2 is performed by gallium chloride series gas as raw material gas of gallium generated in the raw material reaction region R1 and oxygen-containing gas as raw material gas of oxygen. A material of the reaction chamber 20 is quartz glass, for example, but is not particularly limited thereto.

The first heating means 26 and the second heating means 27 can heat the raw material reaction region R1 and the crystal growth region R2 in the reaction chamber 20, respectively. Each of the first heating means 26 and the second heating means 27 is a heating apparatus of a resistive heating system or a radiation heating system, for example, but is not particularly limited thereto.

The reaction chamber 20 includes a first gas introduction port 21, a second gas introduction port 22, a third gas introduction port 23, and an exhaust port 24.

The first gas introduction port 21 is a port for introducing chlorine-containing gas containing Cl₂ gas or HCl gas into the raw material reaction region R1 in the reaction chamber 20 using inactive carrier gas. The inactive carrier gas is nitrogen gas (N₂), argon gas (Ar), or helium gas (He), for example, and the same applies to the description hereinafter.

The second gas introduction port 22 is a port introducing oxygen-containing gas containing oxygen gas (O₂) or water vapor gas (H₂O) and raw material gas of an added element for adding impurity such as Si to the Ga₂O₃ epitaxial growth layer 2 into the crystal growth region R2 in the reaction chamber 20 using the inactive carrier gas.

The third gas introduction port 23 is a port for introducing the inactive carrier gas into the crystal growth region R2 in the reaction chamber 20.

The exhaust port 24 is a port for exhausting gas which is not used in the crystal growth region R2 in the reaction chamber 20 to an outer side of the reaction chamber 20.

Described next is an example of forming the Ga₂O₃ epitaxial growth layer 2 according to the present embodiment 1 using the HVPE method.

An atmosphere temperature of the raw material reaction region R1 is kept at a predetermined temperature by heating the raw material reaction region R1 in the reaction chamber 20 using the first heating means 26.

Next, the chlorine-containing gas is introduced from the first gas introduction port 21 using the carrier gas, and a gallium metal body and the chlorine-containing gas in the reaction container 25 are reacted under an atmosphere temperature kept at a predetermined temperature in the raw material reaction region R1 to generate gallium chloride series gas. The gallium chloride series gas which has been generated includes GaCl gas and the other gallium chloride series gas except for GaCl gas. GaCl₂ gas, GaCl₃ gas, and (GaCl₃) 2 gas, for example, are assumed as the other gallium chloride series gas.

The GaCl gas can increase growth drive force of Ga₂O₃ series single crystal more than the other gallium chloride series gas. In other words, the GaCl gas can keep a temperature capable of increasing a growth speed thereof. Growth at a high temperature is effective to form the Ga₂O₃ epitaxial growth layer 2 having high impurity and high quality. As described above, gallium chloride series gas having high partial pressure of GaCl gas is preferably generated.

In order to achieve this, the atmosphere temperature in the raw material reaction region R1 is preferably a temperature at which a partial pressure ratio of the GaCl gas is higher than that of the other gallium chloride series gas. Specifically, it is preferable that the atmosphere temperature of the raw material reaction region R1 is kept at 300° C. or higher at which the partial pressure ratio of the GaCl gas gets high by the first heating means 26 to react the gallium metal body and the chlorine-containing gas in the reaction container 25. For example, when the atmosphere temperature of the raw material reaction region R1 is 850° C., the partial pressure ratio of the GaCl gas is decisively high, and the other gallium chloride series gas hardly contributes to the growth of the Ga₂O₃ series single crystal.

The gallium metal body and the chlorine-containing gas in the reaction container 25 are preferably reacted while the atmosphere temperature of the raw material reaction region R1 is kept at 1000° C. or lower in consideration of a lifetime of the first heating means 26 and heat resistance of the reaction chamber 20 made up of quartz glass, for example.

When the atmosphere in which the Ga₂O₃ epitaxial growth layer 2 is grown does not contain hydrogen, crystal growth drive force of the Ga₂O₃ epitaxial growth layer 2 is increased, and the growth speed can be increased, Thus, the gallium chloride series gas may be Cl₂ gas without hydrogen, for example, generated by reacting a gallium raw material and the chlorine-containing gas without hydrogen, and the oxygen-containing gas may be O₂ gas without hydrogen, for example.

According to the manufacturing method described above, the growth speed of the Ga₂O₃ epitaxial growth layer 2 can be 1 μm or higher per unit hour, that is to say, 1 μm/h or higher.

Next, the gallium chloride series gas generated in the raw material reaction region R1 and the oxygen-containing gas introduced from the second gas introduction port 22 are mixed in the crystal growth region R2, and the Ga₂O₃ single-crystal substrate 1 is exposed to the mixed gas. Accordingly, the Ga₂O₃ epitaxial growth layer 2 is epitaxially grown on the Ga₂O₃ single-crystal substrate 1. At this time, pressure in the crystal growth region R2 in a furnace housing the reaction chamber 20 is kept at 1 atm, for example.

When the Ga₂O₃ epitaxial growth layer 2 containing Si or Al, for example, as an added element is formed, raw material gas of the added element is added to the gallium chloride series gas and the oxygen-containing gas to be introduced from the second gas introduction port 22 to the crystal growth region R2. For example, when the Ga₂O₃ epitaxial growth layer 2 containing Si as the added element is formed, chloride series gas such as silicon tetrachloride (SiCl₄) is used as the raw material gas of the added element. It is preferable that a ratio of supply partial pressure of the O₂ gas to supply partial

pressure of the GaCl gas in the crystal growth region R2 is 0.5 or larger and the growth temperature is 900 C.° or higher from a viewpoint of effective growth of the Ga₂O₃ epitaxial growth layer 2. Focusing only on the efficient growth of the Ga₂O₃ epitaxial growth layer 2, it is more preferable that the growth temperature is approximately 1000° C. or higher. The growth temperature falls under at least one of the atmosphere temperature in the reaction chamber 20 and the temperature of the Ga₂O₃ single-crystal substrate 1, for example.

The Ga₂O₃ epitaxial growth layer 2 formed using the HVPE method contains chlorine having a concentration of approximately 5×10¹⁶ atoms/cm³ or lower. This is caused by forming the Ga₂O₃ epitaxial growth layer 2 using chlorine-containing gas. The Ga₂O₃ epitaxial growth layer 2 formed by a method other than the HVPE method in which the chlorine-containing gas is used does not normally contain chlorine having a concentration of 5×10¹⁶ atoms/cm³ or higher.

A residual carrier concentration of the Ga₂O₃ epitaxial growth layer 2 formed using the HVPE method is 1×10¹³/cm³ or lower. Thus, when an IV group element such as Si is doped with impurity, a carrier concentration of the Ga₂O₃ epitaxial growth layer 2 can be controlled within a range of 1×10¹³ to 1×10²⁰/cm³, that is to say, a range of 3×10¹⁵/cm³, for example. The carrier concentration can be measured by a capacitance-voltage (C-V) method, for example.

### Conclusion of Embodiment 1

According to the present embodiment 1 described above, the plane direction of each of the first main surface of the Ga₂O₃ single-crystal substrate 1 and the second main surface of the Ga₂O₃ epitaxial growth layer 2 is the (011) plane and the plane in proximity to the (011) plane. According to such a configuration, the defect density of the first main surface and the second main surface can be reduced, and the leakage current of the device can be reduced and reverse withstand voltage can be increased, thus the device characteristics can be increased.

When the Ga₂O₃ epitaxial growth layer 2 is formed by the HVPE method using the gallium chloride series gas and the oxygen-containing gas, a deposition rate and uniformity of an in-plane distribution of a film thickness can be increased, and a large diameter can be achieved.

When the partial voltage ratio of the GaCl gas is higher than that of the other gallium chloride series gas in the gallium chloride series gas, the Ga₂O₃ epitaxial growth layer 2 having high impurity and high quality can be formed, and the growth drive force thereof can be increased.

When H₂O is used as a raw material of oxygen, surface flatness of the Ga₂O₃ epitaxial growth layer 2 can be improved.

### Embodiment 2

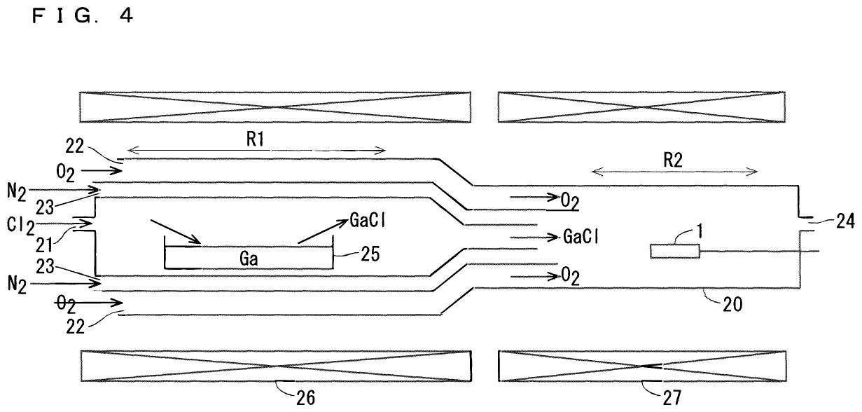

FIG. 4 is a cross-sectional view schematically exemplifying a configuration of a semiconductor device according to the present embodiment 2. The semiconductor device according to the present embodiment 2 is a Schottky barrier diode (SBD) including the Ga₂O₃ single-crystal lamination structure according to the embodiment 1. However, the semiconductor device according to the present embodiment 2 is not limited to the SBD, but may be the other semiconductor diode or a semiconductor device other than these diodes.

The semiconductor device in FIG. 4 includes the Ga₂O₃ single-crystal substrate 1 and the Ga₂O₃ epitaxial growth layer 2 described above, and also includes an anode electrode 3 and a cathode electrode 4. The anode electrode 3 is a Schottky electrode provided on the upper surface of the Ga₂O₃ epitaxial growth layer 2 to be electrically Schottky bonded to the Ga₂O₃ epitaxial growth layer 2. The cathode electrode 4 is an ohmic electrode provided on the lower surface, which is a surface on a side opposite to the Ga₂O₃ epitaxial growth layer 2, of the Ga₂O₃ single-crystal substrate 1 to be electrically ohmic bonded to the Ga₂O₃ single-crystal substrate 1.

The electronic carrier concentration of the Ga₂O₃ single-crystal substrate 1 containing the n-type impurity is a total concentration of the oxygen defect and the n-type impurity. The electronic carrier concentration of the Ga₂O₃ single-crystal substrate 1 may be equal to or larger than 1×10¹⁷ cm⁻³ and equal to or smaller than 1×10¹⁹ cm⁻³, for example. The impurity concentration of the Ga₂O₃ single-crystal substrate 1 may be higher than a numeral range described above to reduce contact resistance of the Ga₂O₃ single-crystal substrate 1 and the cathode electrode 4.

The Ga₂O₃ epitaxial growth layer 2 is provided on the upper surface of the Ga₂O₃ single-crystal substrate 1. The electronic carrier concentration of the Ga₂O₃ epitaxial growth layer 2 is preferably lower than that of the Ga₂O₃ single-crystal substrate 1, and may be equal to or larger than 1×10¹⁵ cm⁻³ and equal to or smaller than 1×10¹⁷ cm⁻³, for example.

The anode electrode 3 is provided on the upper surface of the Ga₂O₃ epitaxial growth layer 2. The anode electrode 3 is Schottky bonded to the Ga₂O₃ epitaxial growth layer 2, thus is preferably made up of a metal material having a larger work function than that of the Ga₂O₃ epitaxial growth layer 2.

Such a metal material may be platinum (Pt), nickel (Ni), gold (Au), or palladium (Pd), for example. The anode electrode 3 may have a lamination structure in which a plurality of metal materials are laminated. For example, it is applicable that a first layer made up of a metal material suitable for Schottky bonding to the Ga₂O₃ epitaxial growth layer 2 is disposed to have contact with the Ga₂O₃ epitaxial growth layer 2, and a second layer made up of the other metal material is disposed on an upper surface of the first layer to constitute the anode electrode 3.

The cathode electrode 4 is disposed on the lower surface of the Ga₂O₃ single-crystal substrate 1. The cathode electrode 4 is ohmic bonded to the Ga₂O₃ single-crystal substrate 1, thus is preferably made up of a metal material having a work function smaller than that of the Ga₂O₃ single-crystal substrate 1. The cathode electrode 4 is preferably made up of a metal material to have small contact resistance with the Ga₂O₃ single-crystal substrate 1 by thermal processing after being formed on the Ga₂O₃ single-crystal substrate 1.

Titanium (Ti), for example, may be applied to such a metal material. The cathode electrode 4 may have a lamination structure in which a plurality of metal materials are laminated in the manner similar to the anode electrode 3. For example, when a metal material which is easily oxidized has contact with the lower surface of the Ga₂O₃ single-crystal substrate 1, the cathode electrode 4 having a lamination structure in which a metal material which is hardly oxidized is further formed on a lower surface of the metal material. It is also applicable that a first layer having contact with the Ga₂O₃ single-crystal substrate 1 and made up of Ti suitable for ohmic bonding is disposed, and a second layer made of gold (Au) or silver (Ag) is disposed on a lower surface of the first layer to constitute the cathode electrode 4, for example. The cathode electrode 4 may be wholly or partially disposed on the lower surface of the Ga₂O₃ single-crystal substrate 1.

According to the embodiment 2 described above, the semiconductor device having increased device characteristics can be achieved by using the lamination crystal structure according to the embodiment 1.

### Embodiment 3

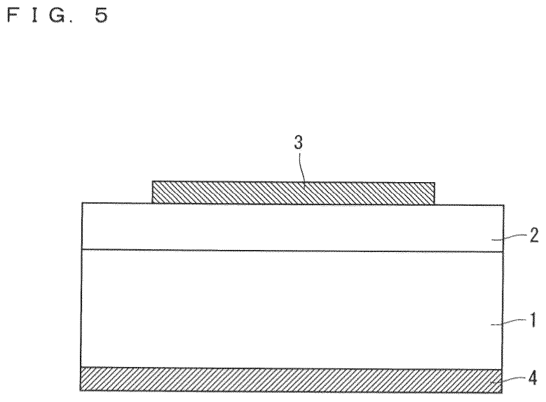

FIG. 5 is a cross-sectional view schematically exemplifying a configuration of a semiconductor device according to the present embodiment 3. The semiconductor device according to the present embodiment 3 is a horizontal Schottky gate transistor including the Ga₂O₃ single-crystal lamination structure according to the embodiment 1. However, the semiconductor device according to the present embodiment 3 is not limited to the horizontal Schottky gate transistor, but may also be the other semiconductor switching element having a gate insulating film or a semiconductor device other than these transistor or element.

The semiconductor device in FIG. 5 includes the Ga₂O₃ single-crystal substrate 1 and the Ga₂O₃ epitaxial growth layer 2 described above, and also includes a source electrode 5, a drain electrode 6, and a gate electrode 7. The source electrode 5 and the drain electrode 6 are ohmic electrodes provided to be away from each other on the upper surface of the Ga₂O₃ epitaxial growth layer 2 to be electrically ohmic bonded to the Ga₂O₃ epitaxial growth layer 2. The gate electrode 7 is a Schottky electrode provided between the source electrode 5 and the drain electrode 6 on the upper surface of the Ga₂O₃ epitaxial growth layer 2 to be electrically Schottky bonded to the Ga₂O₃ epitaxial growth layer 2.

A direction in which current flows is a lateral direction in the semiconductor device according to the present embodiment 3, thus the electronic carrier concentration of the Ga₂O₃ epitaxial growth layer 2 is higher than that of the Ga₂O₃ single-crystal substrate 1. This point is different from the vertical semiconductor element described in the embodiment 2, and such a Ga₂O₃ epitaxial growth layer 2 can be formed by adjusting a concentration of the n-type impurity thereof.

The electronic carrier concentration of the Ga₂O₃ single-crystal substrate 1 containing the n-type impurity is a total concentration of the oxygen defect and the n-type impurity. The electronic carrier concentration of the Ga₂O₃ single-crystal substrate 1 may be equal to or larger than 1×10¹² cm⁻³ and equal to or smaller than 1×10¹⁵ cm⁻³, for example. The electronic carrier concentration of the Ga₂O₃ single-crystal substrate 1 does not contribute to a flow of current, thus the impurity concentration may be lower than the numeral range described above. That is to say, iron (Fe), for example, may be added to the Ga₂O₃ single-crystal substrate 1 to intentionally make the Ga₂O₃ single-crystal substrate 1 have semi-insulating properties.

In the meanwhile, the impurity concentration and the electronic carrier concentration of the Ga₂O₃ epitaxial growth layer 2 is preferably higher than that of the Ga₂O₃ single-crystal substrate 1, and the electronic carrier concentration thereof may be equal to or larger than 1×10¹⁵ cm⁻³ and equal to or smaller than 1×10¹⁷ cm⁻³, for example.

The source electrode 5 and the drain electrode 6 are ohmic bonded to the Ga₂O₃ epitaxial growth layer 2, thus is preferably made up of a metal material having a smaller work function than that of the Ga₂O₃ epitaxial growth layer 2. The source electrode 5 and the drain electrode 6 are preferably made up of a metal material to have small contact resistance with the Ga₂O₃ epitaxial growth layer 2 by thermal processing after being formed on the Ga₂O₃ epitaxial growth layer 2. Titanium (Ti), for example, may be applied to such a metal material. The source electrode 5 and the drain electrode 6 may have a lamination structure in the manner similar to the cathode electrode 4 described in the embodiment 2.

The gate electrode 7 is Schottky bonded to the Ga₂O₃ epitaxial growth layer 2, thus is preferably made up of a metal material having a larger work function than that of the Ga₂O₃ epitaxial growth layer 2. Such a metal material may be platinum (Pt), nickel (Ni), gold (Au), or palladium (Pd), for example. The gate electrode 7 may have a lamination structure in the manner similar to the anode electrode 3 described in the embodiment 2.

Each embodiment and each modification example can be arbitrarily combined, or each embodiment and each modification example can be appropriately varied or omitted within the scope of the invention.

The foregoing description is in all aspects illustrative and does not restrict the disclosure. It is therefore understood that numerous modification examples not illustrated can be devised.

### EXPLANATION OF REFERENCE SIGNS

1 Ga₂O₃ single-crystal substrate, 2 Ga₂O₃ epitaxial growth layer, 3 anode electrode, 4 cathode electrode, 5 source electrode, 6 drain electrode, 7 gate electrode

1. A crystal lamination structure, comprising:
a Ga₂O₃ single-crystal substrate having a first main surface and having a β-type crystal structure; and
a Ga₂O₃ single-crystal layer as an epitaxial growth layer provided on the first main surface of the Ga₂O₃ single-crystal substrate and having a second main surface on a side opposite to the Ga₂O₃ single-crystal substrate and having a β-type crystal structure, wherein
a plane direction of each of the first main surface of the Ga₂O₃ single-crystal substrate and the second main surface of the Ga₂O₃ single-crystal layer is plane.

2. The crystal lamination structure according to claim 1, wherein
the Ga₂O₃ single-crystal layer includes chlorine.

3. The crystal lamination structure according to claim 1, wherein
a residual carrier concentration of the Ga₂O₃ single-crystal layer is 3×10¹⁵/cm³ or lower.

4. The crystal lamination structure according to claim 2, wherein
a concentration of chlorine of the Ga₂O₃ single-crystal layer is 5×10¹⁶ atoms/cm³ or lower.

5. A method of manufacturing a crystal lamination structure, comprising:
preparing a Ga₂O₃ single-crystal substrate having a first main surface and having a β-type crystal structure; and
forming a Ga₂O₃ single-crystal layer as an epitaxial growth layer having a second main surface on a side opposite to the Ga₂O₃ single-crystal substrate on the first main surface of the Ga₂O₃ single-crystal substrate by gallium chloride series gas and oxygen-containing gas and having β-type crystal structure, wherein
a plane direction of each of the first main surface of the Ga₂O₃ single-crystal substrate and the second main surface of the Ga₂O₃ single-crystal layer is plane.

6. The method of manufacturing the crystal lamination structure according to claim 5, wherein
the Ga₂O₃ single-crystal layer is formed under a growth temperature of 900° C. or higher,
the gallium chloride series gas is generated by reacting a gallium raw material and chlorine-containing gas without hydrogen, and
each of the gallium chloride series gas and the oxygen-containing gas does not contain hydrogen.

7. The method of manufacturing the crystal lamination structure according to claim 6, wherein
the oxygen-containing gas is O₂ gas.

8. The method of manufacturing the crystal lamination structure according to claim 6, wherein
the chlorine-containing gas is Cl₂ gas.

9. The method of manufacturing the crystal lamination structure according to claim 5, wherein
the gallium chloride series gas is generated by reacting a gallium metal body and chlorine-containing gas including Cl₂ gas or HCl gas.

10. The method of manufacturing the crystal lamination structure according to claim 6, wherein
the gallium chloride series gas is generated under an atmosphere temperature of 300° C. or higher.

11. The method of manufacturing the crystal lamination structure according to claim 6, wherein
the gallium chloride series gas includes GaCl gas and another gallium chloride series gas except for GaCl gas, and
a partial pressure ratio of GaCl gas is higher than a partial pressure ratio of the another gallium chloride series gas.

12. The method of manufacturing the crystal lamination structure according to claim 5, wherein
a growth speed of the Ga₂O₃ single-crystal layer is equal to or larger than 1 μm/h.

13. A semiconductor device, comprising:
the crystal lamination structure according to claim 1;
a Schottky electrode provided on the second main surface of the Ga₂O₃ single-crystal layer; and
an ohmic electrode provided on a surface of the Ga₂O₃ single-crystal substrate on a side opposite to the Ga₂O₃ single-crystal layer, wherein
a carrier concentration of the Ga₂O₃ single-crystal layer is lower than a carrier concentration of the Ga₂O₃ single-crystal substrate.

14. A semiconductor device, comprising:
the crystal lamination structure according to claim 1:
a source electrode and a drain electrode provided away from each other on the second main surface of the Ga₂O₃ single-crystal layer; and
a gate electrode provided on the second main surface of the Ga₂O₃ single-crystal layer between the source electrode and the drain electrode.
